(19) United States
(12) Patent Application Publication
(10) Pub. No.: US 2015/0380301 A1
(43) Pub. Date: Dec. 31, 2015

(54) SEMICONDUCTOR DEVICE AND METHOD OF MANUFACTURING THE SAME

(71) Applicant: KABUSHIKI KAISHA TOSHIBA, Tokyo (JP)

(72) Inventor: Tomonori AOYAMA, Yokkaichi (JP)

(21) Appl. No.: 14/618,028

(22) Filed: Feb. 10, 2015

(30) Foreign Application Priority Data
Jun. 26, 2014 (JP) 2014-131645

(51) Int. Cl. H01L 21/768; H01L 21/306; H01L 21/311; H01L 21/265; H01L 27/115; H01L 29/788; H01L 29/08; H01L 29/04; H01L 23/528; H01L 29/66; H01L 29/792

(52) U.S. Cl. CPC H01L 21/76825; H01L 29/66833; H01L 21/30604; H01L 21/76835; H01L 21/31116; H01L 21/26506; H01L 21/76832; H01L 29/792; H01L 21/76802; H01L 21/76897; H01L 29/788; H01L 29/66825; H01L 29/0847; H01L 29/04; H01L 23/528; H01L 21/76879; H01L 27/11565; H01L 27/11568; H01L 27/11519; H01L 27/11521

(57) ABSTRACT

In one embodiment, a method of manufacturing a semiconductor device includes forming a plurality of convex portions on a substrate, forming a first film on upper faces and side faces of the convex portions, and forming a second film on the upper faces and the side faces of the convex portions via the first film. The method further includes removing the second film formed on upper faces of the first film to expose the upper faces of the first film. The method further includes implanting impurities into the convex portions in a state where side faces of the first film are covered with the second film and the upper faces of the first film are exposed. The method further includes annealing the convex portions after implanting the impurities into the convex portions.

### CROSS REFERENCE TO RELATED APPLICATION

This application is based upon and claims the benefit of priority from the prior Japanese Patent Application No. 2014-131645, filed on Jun. 26, 2014, the entire contents of which are incorporated herein by reference.

### FIELD

Embodiments described herein relate to a semiconductor device and a method of manufacturing the same.

### BACKGROUND

In a process of manufacturing a NAND flash memory, contact plugs are formed on device regions in a contact region between select gates. In order to reduce contact resistance between the device regions and the contact plugs, impurities are generally implanted into the device regions to form diffusion regions in the device regions.

However, the implantation of the impurities into the device regions causes volume expansion of the device regions, so that the distance between the device regions becomes shorter. Therefore, if displacement in positioning of a contact hole occurs when forming a contact plug, the contact plug is likely to be formed both on a connection target device region and its adjacent device region, which can cause a short circuit between these device regions. This problem is more likely to arise as the width of the device regions is narrower and the impurity concentration in the device regions is higher. The volume expansion of the device regions can be suppressed by implanting the impurities into the device regions which are covered with a hard film. However, the device regions in this case suffer compressive stress from this film for suppressing the volume expansion. Also, when the width of the device regions is narrow, this compressive stress is strong, so that recrystallization in the device regions may not proceed and therefore amorphous regions or polycrystalline regions may remain in the device regions. Similar problems can arise also in the case where the impurities are implanted into convex portions of semiconductor devices other than the NAND flash memory.

### BRIEF DESCRIPTION OF THE DRAWINGS

FIG. 1 is a plan view illustrating a structure of a semiconductor device of a first embodiment;

FIGS. 2A to 4C are cross-sectional views illustrating a method of manufacturing the semiconductor device of the first embodiment;

FIGS. 5A to 5C are cross-sectional views illustrating a method of manufacturing a semiconductor device of a first comparative example of the first embodiment;

FIG. 6 is a cross-sectional view for explaining a problem in the method of manufacturing the semiconductor device of the first comparative example of the first embodiment; and

FIGS. 7A to 7C are cross-sectional views illustrating a method of manufacturing a semiconductor device of a second comparative example of the first embodiment,

### DETAILED DESCRIPTION

Embodiments will now be explained with reference to the accompanying drawings.

In one embodiment, a method of manufacturing a semiconductor device includes forming a plurality of convex portions on a substrate, forming a first film on upper faces and side faces of the convex portions, and forming a second film on the upper faces and the side faces of the convex portions via the first film. The method further includes removing the second film formed on upper faces of the first film to expose the upper faces of the first film. The method further includes implanting impurities into the convex portions in a state where side faces of the first film are covered with the second film and the upper faces of the first film are exposed. The method further includes annealing the convex portions after implanting the impurities into the convex portions.

### First Embodiment

(1) Structure of Semiconductor Device of First Embodiment

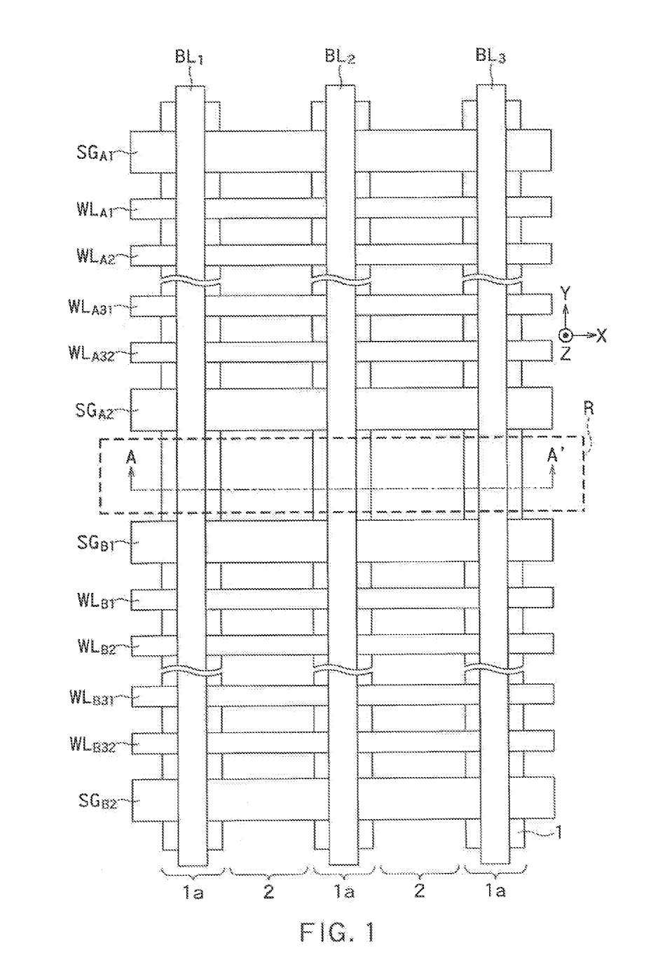

FIG. 1 is a plan view illustrating a structure of a semiconductor device of a first embodiment. The semiconductor device in FIG. 1 is a NAND flash memory.

The semiconductor device in FIG. I includes a substrate 1 having a plurality of device regions la, and includes a plurality of isolation regions 2. The semiconductor device in FIG. 1 further includes word lines WL_{A1} to WL_{A32} and WL_{B1}, to WL_{B32}, select gates (select lines) SG_{A1}, SG_{A2}, SG_{B1} and SG_{B2}, and bit lines BL₁ to BL₃.

An example of the substrate 1 is a semiconductor substrate such as a silicon substrate. FIG. 1 presents an X-direction and a Y-direction which are parallel to a surface of the substrate 1 and perpendicular to each other, and a Z-direction perpendicular to the surface of the substrate 1. The device regions la are formed on the surface of the substrate 1. The device regions la extend in the Y-direction and are adjacent to one another in the X-direction. Each of the device regions la of the present embodiment is also called an active area (AA). The device regions 1a are an example of convex portions of the substrate 1.

Each of the isolation regions 2 is formed between the device regions 1a on the surface of the substrate 1. The isolation regions 2 extend in the Y-direction. An example of the isolation regions 2 is a silicon oxide film. The isolation regions 2 of the present embodiment are also called shallow trench isolations (STIs).

In the specification, the +Z-direction is regarded as an upward direction and the −Z-direction is regarded as a downward direction. For example, positional relation between the substrate 1 and the isolation regions 2 is expressed as that the substrate 1 is positioned below the isolation regions 2. The -Z-direction of the present embodiment may coincide with the direction of the gravity or may not coincide with the direction of the gravity.

The word lines WL_{A1} to WL_{A32} are formed between the select gates SG_{A1} and SG_{A2} on the substrate 1 and extend in the X-direction. Similarly, the word lines WL_{B1} to WL_{B32} are formed between the select gates SG_{B1} and SG_{B2} on the substrate 1 and extend in the X-direction. Moreover; the bit lines BL₁ to BL₃ are formed on the substrate 1 and extend in the Y-direction.

The semiconductor device in FIG. 1 includes cell transistors at intersections of the word lines WL_{A1} to W_{A32} and WL_{B1} to WL_{B32} and the bit lines BL₁ to BL₃, and includes select transistors at intersections of the select gates SG_{A1}, SG_{A2}, SG_{B1} and SG_{B2} and the bit lines BL₁ to BL₃. The cell transistors and the select transistors constitute a plurality of NAND strings extending in the Y-direction.

FIG. 1 illustrates a contact region R between the select gates SG_{A2} and SG_{BI}. The contact region R includes contact plugs formed on the device regions 1a. The device regions 1a in the contact region R include diffusion regions containing p-type or n-type impurities in order to reduce contact resistance between the device regions 1a and the contact plugs. Details of a method of forming the diffusion regions are mentioned later.

(2) Method of Manufacturing Semiconductor Device of First Embodiment

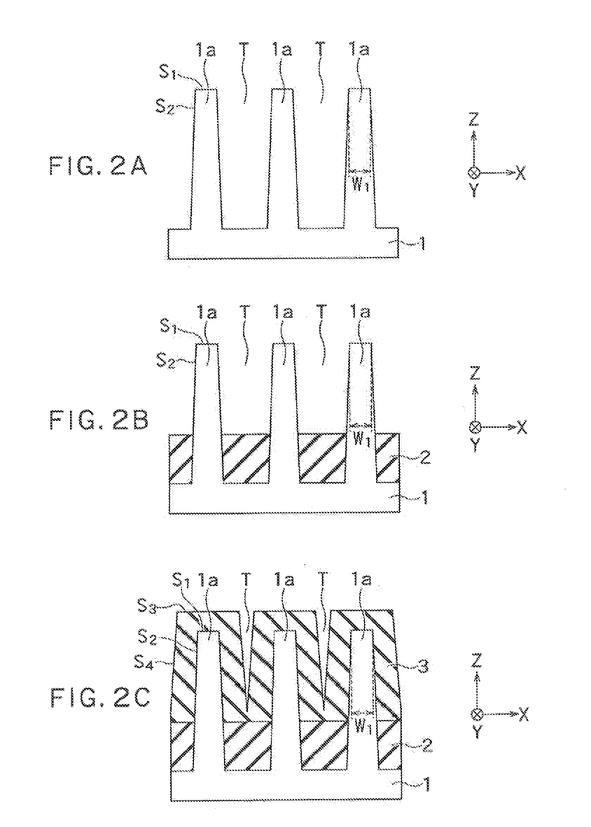

FIGS. 2A to 4C are cross-sectional views illustrating a method of manufacturing the semiconductor device of the first embodiment. FIGS. 2A to 4C are cross-sectional views in manufacturing processes showing a cross-sectional structure of the contact region R taken along the line A-A′ in FIG. 1.

[FIG. 2A]

The plurality of the device regions 1a are formed on the surface of the substrate 1 (FIG. 2A). The device regions 1a are formed by forming a plurality of trenches T extending in the Y-direction on the surface of the substrate 1. Signs S₁ and S₂ designate upper faces and side faces of the device regions 1a, respectively. Sign. W₁ designates a width of the upper faces S₁ of the device regions 1a. The width W₁ of the upper faces S₁ of the device regions 1a of the present embodiment is 20 nm or less.

[FIG. 2B]

The plurality of isolation regions 2 are formed between the device regions 1a on the substrate 1 (FIG. 2B). The isolation regions 2 are formed by forming an insulator (for example, a silicon oxide film) for the isolation regions 2 on the whole surface of the substrate 1 and etching the insulator until the level of upper faces of the insulator becomes lower than that of the upper faces S₁ of the device regions 1a.

[FIG. 2C]

A first insulator 3 is deposited on the whole surface of the substrate 1 (FIG. 2C). As a result, the first insulator 3 is formed on the upper faces S₁ and the side faces S₂ of the device regions 1a. Signs S₃ and S₄ designate upper faces and side faces of the first insulator 3, respectively. The first insulator 3 of the present embodiment is formed such that portions of the trenches T between the device regions 1a remain, FIG. 2C illustrates a state where the trenches T between the device regions 1a are not completely filled with the first insulator 3 but partly remain.

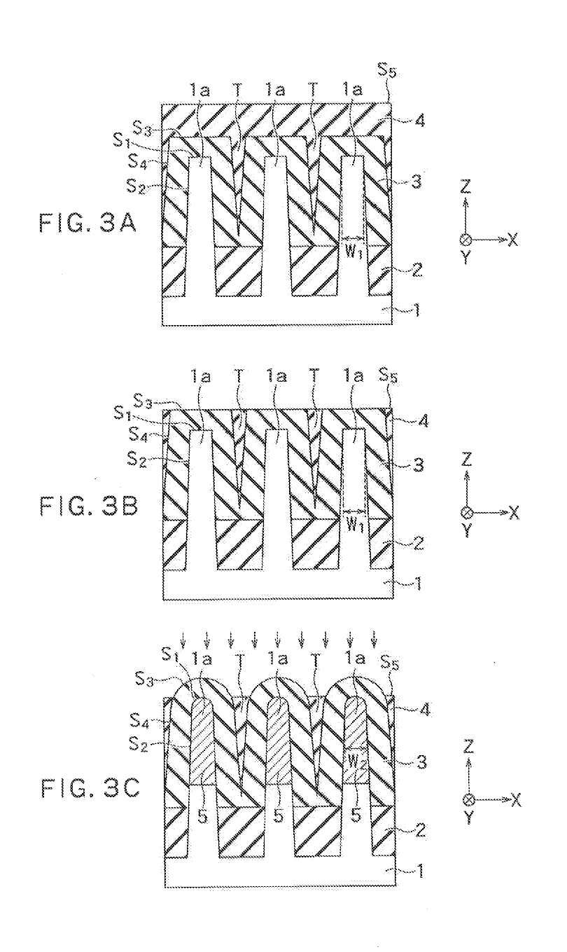

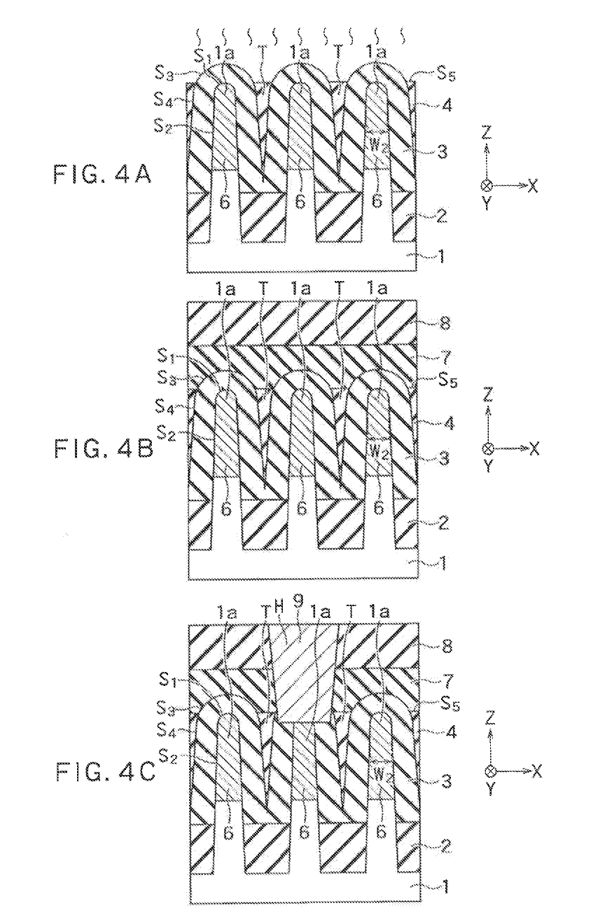

The first insulator 3 of the present embodiment is formed for preventing impurities implanted into the device regions 1a in a process of FIG. 3C from diffusing outside the device regions 1a in an annealing process of FIG. 4A, An example of the first insulator 3 is a silicon oxide film. An example of a thickness of the first insulator 3 is 2 to 3 nm. The first insulator 3 is an example of a first film.

[FIG. 3A]

A second insulator 4 is deposited on the whole surface of the substrate 1 (FIG. 3A). As a result, the second insulator 4 is formed on the upper faces S₁ and the side faces S₂ of the device regions 1a via the first insulator 3. Sign S₅ designates an upper face of the second insulator 4. The second insulator 4 of the present embodiment is formed such that the above-mentioned portions of the trenches T between the device regions 1a are filled up to eliminate the trenches T. FIG. 3A illustrates a state where the trenches T between the device regions 1a are completely filled with the first and second insulators 3 and 4 and eliminated.

The second insulator 4 of the present embodiment is formed for suppressing volume expansion of the device regions 1a in a process of FIG. 3C. Therefore, the second insulator 4 of the present embodiment is formed of an insulator harder than the first insulator 3. An example of the second insulator 4 is a silicon nitride film or a silicon carbide film. The second insulator is an example of a second film.

[FIG. 3B]

The upper face S₅ of the second insulator 4 is etched back by reactive ion etching (RIE) to remove the second insulator 4 that is formed on the upper faces S₃ of the first insulator 3 (FIG. 3B). As a result, the first insulator 3 is allowed in a state where the side faces S₄ are covered with the second insulator 4 and the upper faces S₃ are exposed from the second insulator 4. FIG. 3B shows the second insulator 4 formed between the side faces S₂ of adjacent device regions 1a via the first insulator 3.

The etching-back of the second insulator 4 may be terminated immediately after the upper faces S₃ of the first insulator 3 have been exposed from the second insulator 4, or may be continued even after the upper faces S₃ of the first insulator 3 have been exposed from the second insulator 4. In the latter case of etching-back, note that it is terminated before the upper faces Sof the device regions 1a are exposed from the first insulator 3.

[FIG. 3C]

In the state where the side faces S₄ of the first insulator 3 are covered with the second insulator 4 and the upper faces S₃ of the first insulator 3 are exposed from the second insulator 4, impurity ions are implanted into the device regions 1a through the first insulator 3 (FIG. 3C). As a result, portions in the device regions 1a in which the impurities are implanted are changed to amorphous regions 5. An example of the amorphous regions 5 is amorphous silicon regions. An example of the impurities is arsenic: The ion implantation of the present embodiment is performed such that a concentration of arsenic in the device regions 1a is 1.0×10²⁰ cm⁻³ or more.

In the ion implantation of the present embodiment, the side faces S₂ of the device regions 1a are covered with the second insulator 4 via the first insulator 3. Therefore, according to the present embodiment, expansion of the device regions 1a in the lateral direction can be suppressed by the second insulator 4. As a result, the shapes of the side faces S₂ of the device regions 1a are hardly changed by the ion implantation and are maintained to be substantially flat faces. Similarly, the shapes of the side faces S₄ of the first insulator 3 are also hardly changed by the ion implantation and are maintained to be substantially flat faces.

Moreover, in the ion implantation of the present embodiment, the upper faces S₁ of the device regions 1a are not covered with the second insulator 4. Therefore, according to the present embodiment, the device regions 1a can be allowed to expand substantially only in the upward direction. As a result, the shapes of the upper faces S₁ of the device regions 1a are changed by the ion implantation from flat faces to convex faces. As the device regions 1a expand in the upward direction, the shapes of the upper faces S₃ of the first insulator 3 are also changed from flat faces to convex shapes. As a result, positions of the upper faces S₃ of the first insulator 3 are entirely or partially higher than the positions of the upper faces S₅ of the second insulator 4.

When the volume expansion of the device regions 1a is suppressed both in the lateral direction and in the upward direction, the device region 1a cannot expand at all. Therefore, the device regions 1a suffer compressive stress of suppressing the volume expansion from the second insulator 4. However, according to the present embodiment, the device regions 1a are allowed to expand in the upward direction, and thereby the compressive stress can be relieved.

As mentioned above, sign W₁ designates the width of the upper faces S₁ of the device regions 1a before the ion implantation. On the other hand, sign W₂ designates a width of the upper faces S₁ of the device regions 1a after the ion implantation. In the present embodiment, since the device regions 1a expand substantially only in the upward direction, the width W₂ has substantially no change from the width W₁ (W₂≈W₁). In the present embodiment, the width W₂ of the upper face S₁ of the device region 1a after the ion implantation is also 20 nm or less.

In the present embodiment, when a boundary between an upper face S₁ and a side face S₂ of a device region 1a after the ion implantation is indefinite, a convex face in the vicinity of the boundary is regarded as a portion of the upper face S. the device region 1a, and a flat face or a substantially flat face in the vicinity of the boundary is regarded as a portion of the side face S₂ of the device region 1a. Similarly, in the present embodiment, when a boundary between an upper face S₃ and a side face S₄ of the first insulator 3 after the ion implantation is indefinite, a convex face in the vicinity of the boundary is regarded as a portion of the upper face S₃ of the first insulator 3, and a flat face or a substantially flat face in the vicinity of the boundary is regarded as a portion of the side face S₄ of the first insulator 3.

[FIG. 4A]

The device regions 1a are annealed after the implantation of the impurity ions into the device regions 1a (FIG. 4A). As a result, recrystallization proceeds from lower portions to upper portions in the amorphous regions 5, and the amorphous regions 5 change to single-crystalline or twin-crystalline diffusion regions 6. The device regions 1a of the present embodiment are annealed using microwave annealing of irradiating the front face or back face of the substrate 1 with a microwave. In the present embodiment, the microwave annealing is performed such that a temperature of the device regions 1a during the annealing is 490° C. or more and 900° C. or less (preferably, 490° C. or more and 850° C. or less).

In the present embodiment, since the device regions 1a are allowed to expand in the upward direction in the ion implantation process, the compressive stress from the second insulator 4 is not much exerted on portions in the vicinity of the upper faces S₁ of the device regions 1a. Therefore, according to the present embodiment, the recrystallization in the amorphous regions 5 can be sufficiently allowed to proceed. The amorphous regions 5 can be changed to the single-crystalline or twin-crystalline diffusion regions 6 so as not to remain. FIG. 4A illustrates the single-crystalline or twin-crystalline diffusion regions 6 which spread up to the upper faces S₁ of the device regions 1a.

After the ion implantation of the present embodiment, the width W₂ of the upper faces S₁ of the device regions 1a is 20 nm or less. When such narrow device regions 1a with the width W₂ are annealed at a high temperature, portions in the vicinity of the upper faces S₁ of the device regions 1a become polycrystalline, which causes large contact resistance. Therefore, the annealing of the device regions 1a of the present embodiment is performed at a low temperature of 490° C. or more and 900° C. or less for suppressing polycrystallization of the device regions 1a.

The device regions 1a of the present embodiment may be annealed using a method other than the microwave annealing. It should be noted that usage of the method other than the microwave annealing results in a long time for annealing the device regions 1a when the device regions 1a are annealed at the low temperature of 490° C. or more and 900° C. or less. On the other hand, usage of the microwave annealing allows sufficient annealing of the device regions 1a in a short time when the device regions 1a are annealed at the low temperature of 490° C. or more and 900° C. or less. This is because the microwave can be absorbed at the amorphous/single crystal interface in the device regions 1a. The microwave annealing of the present embodiment can conduct solid-state epitaxial growth of single crystals or twin crystals of the amorphous regions 5 from their lower portions in high speed. Furthermore, the single-crystallization or twin-crystallization is allowed to proceed up to the upper portions of the amorphous regions 5, which can suppress the contact resistance from increasing.

[FIG. 4B]

After the annealing of the device regions 1a, a third insulator 7 and an inter layer dielectric 8 are sequentially deposited on the whole surface of the substrate 1 (FIG. 4B), As a result, the third insulator 7 is formed on the first and second insulators 3 and 4. An example of the third insulator 7 is a silicon nitride film, and an example of the inter layer dielectric 8 is a silicon oxide film. The third insulator 7 is an example of a third film.

[FIG. 4C]

A contact hole H which penetrates the inter layer dielectric 8, the third insulator 7 and the first insulator 3 to reach a device region 1a is formed. A contact plug 9 is then formed on the device region 1a in the contact hole H (FIG. 4C). An example of the contact plug 9 is a metal layer containing a barrier metal layer and a plug layer. The contact hole H and the contact plug 9 are examples of an opening and a plug interconnect, respectively.

Thereafter; various inter layer dielectrics, interconnect layers, via plugs, passivation films and the like are formed on the substrate 1. In this way, the semiconductor device of the first embodiment is manufactured.

(3) Comparative Examples of First Embodiment

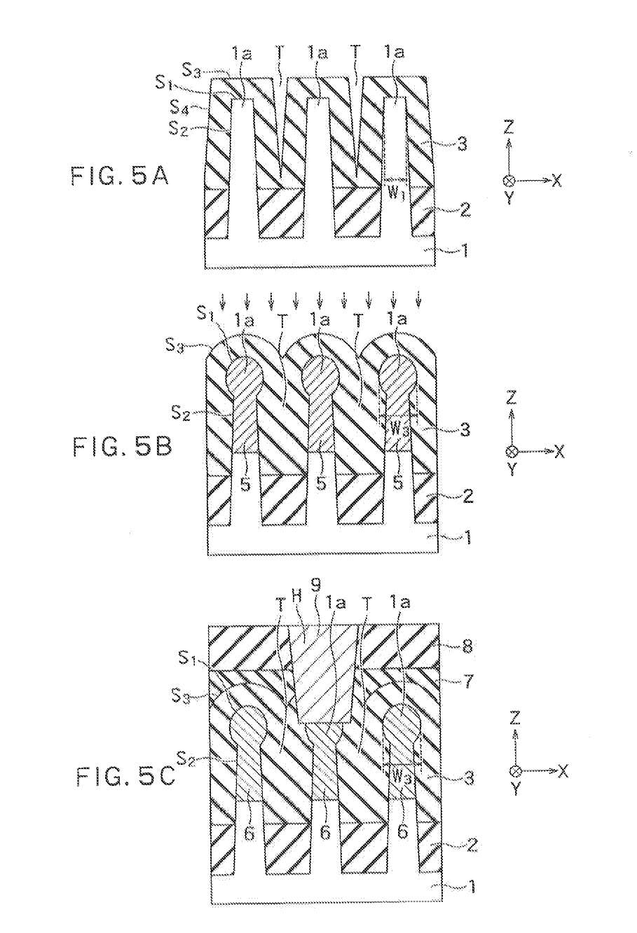

The first embodiment will be compared with comparative examples with reference to FIGS. 5A to 7C.

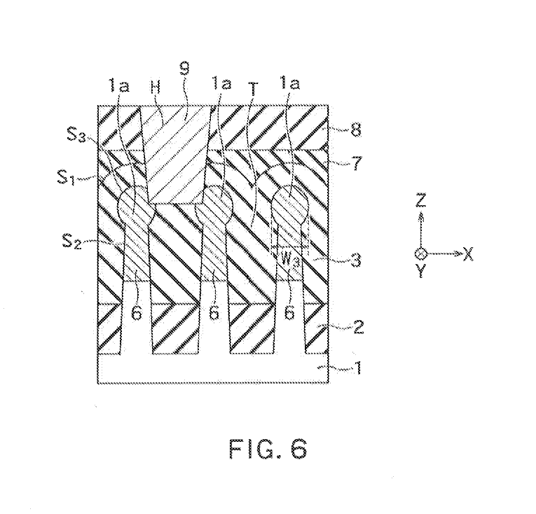

FIGS. 5A to 5C are cross-sectional views illustrating a method of manufacturing a semiconductor device of a first comparative example of the first embodiment. FIG. 6 is a cross-sectional view for explaining a problem in the method of manufacturing the semiconductor device of the first comparative example of the first embodiment. FIGS. 5A to 5C and 6 are cross-sectional views in the manufacturing processes showing the cross-sectional structure of the contact region R taken along the line A-A′ in FIG. 1.

FIG. 5A illustrates the process corresponding to FIG. 2C. In this comparative example, the ion implantation is performed without forming the second insulator 4 on the upper faces S₃ or the side faces S₄ of the first insulator 3 (FIG. 5B). As a result, the device regions 1a expand in the lateral direction and in the upward direction,

Sign W₃ designates a width of the upper faces S₁ of the device regions 1a after the ion implantation. In this comparative example, since the device regions 1a expand in the lateral direction, the width W₃ is wider than the width W₁ (W₃>W₁).

FIG. 5C illustrates the process corresponding to FIG. 4C. In this comparative example, the device regions 1a expand in the lateral direction and in the upward direction and the distance between the device regions 1a becomes short. Therefore, in the case where positioning of the contact hole H is displaced, the contact plug 9 is highly possibly formed both on a connection target device region 1a and on its adjacent device region 1a. Accordingly, there is a concern that these device regions 1a suffer a short circuit (FIG. 6).

On the other hand, in the present embodiment, the ion implantation is performed in the state where the side faces S₄ of the first insulator 3 are covered with the second insulator 4 and the upper faces S₃ of the first insulator 3 are exposed from the second insulator 4 (FIG. 3C). As a result, the device regions 1a are allowed to expand substantially only in the upward direction and the distance between the device regions 1a is not much changed. Therefore, the present embodiment can reduce the possibility that the device regions 1a suffer a short circuit when positioning of the contact hole H is displaced.

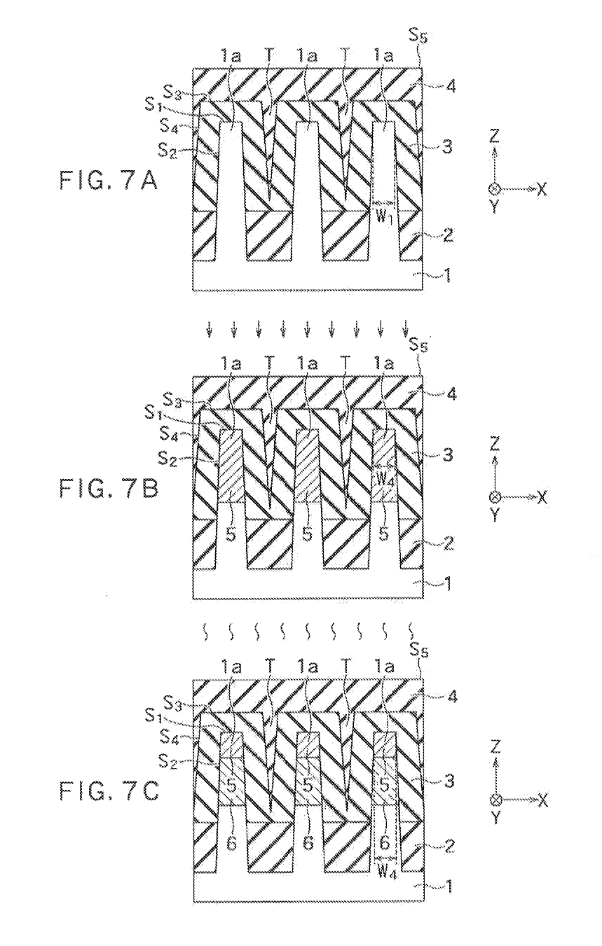

FIGS. 7A to 7C are cross-sectional views illustrating a method of manufacturing a semiconductor device of a second comparative example of the first embodiment. FIGS. 7A to 7C are cross-sectional views in the manufacturing processes showing the cross-sectional structure of the contact region R taken along the line A-A′ in FIG. 1.

FIG. 7A illustrates the process corresponding to FIG. 3A. In this comparative example, the ion implantation is performed without exposing the upper faces S₃ of the first insulator 3 from the second insulator 4 (FIG. 7B). Therefore, the device regions 1a are neither allowed to expand substantially in the lateral direction nor in the upward direction. Accordingly, strong compressive stress is exerted on the device regions 1a from the second insulator 4.

Sign W₄ designates a width of the upper faces S₁ of the device regions 1a after the ion implantation. In this comparative example, since the device regions 1a are not allowed to expand substantially in the lateral direction, the width W₄ is not almost changed from the width W₁ (W₄≈W₁).

FIG. 7C illustrates the process corresponding to FIG. 4A. In this comparative example, the microwave annealing is performed in the state where the strong compressive stress is exerted on the device regions 1a. Accordingly, there is a possibility that the amorphous regions 5 (or polycrystalline regions) remain in the device regions 1a. FIG. 7C illustrates the amorphous regions 5 that remain in the upper portions of the device regions 1a.

On the other hand, in the present embodiment, the microwave annealing is performed in the state where the compressive stress on the device regions 1a is relieved by the device regions 1a allowed to expand in the upward direction (FIG. 4A). Therefore, the present embodiment can change the amorphous regions 5 to the single-crystalline or twin-crystalline diffusion regions 6 so as not to remain, and can therefore reduce the contact resistance between the device regions 1a and the contact plugs 9.

As described above, the impurities in the present embodiment are implanted into the device regions 1a in the state where the side faces S₄ of the first insulator 3 are covered with the second insulator 4 and the upper faces S₃ of the first insulator 3 are exposed from the second insulator 4. Therefore, the present embodiment can allow the device regions 1a to expand substantially only in the upward direction, and can therefore suppress a short circuit between the device regions 1a caused by displacement in positioning of the contact hole H.

Moreover, the device regions 1a in the present embodiment are annealed after the device regions 1a are allowed to expand substantially only in the upward direction. Therefore, the present embodiment can anneal the device regions 1a in the state where the compressive stress on the device regions 1a is relieved, and can therefore change the amorphous regions 5 to the single-crystalline or twin-crystalline diffusion regions 6 so as not to remain. Therefore, the present embodiment makes it possible to reduce the contact resistance between the device regions 1a and the contact plugs 9.

Moreover, the device regions 1a in the present embodiment are allowed to expand substantially only in the upward direction, so that the upper faces S₁ of the device regions 1a and the upper faces S₃ of the first insulator 3 are changed to be the convex faces, and the positions of the upper faces S₃ of the first insulator 3 become entirely or partially higher than the positions of the upper faces S₅ of the second insulator 4. Such a structure has an advantage that the areas of the upper faces S₁ of the device regions 1a are increased and the contact resistance is reduced compared with the case where the upper faces S₁ of the device regions 1a are the flat faces.

In this manner, the present embodiment makes it possible to suppress occurrences of malfunctions such as a short circuit in the device regions 1a and increase in contact resistance. The present embodiment can also be applied to convex portions of semiconductor devices other than the NAND flash memory.

While certain embodiments have been described, these embodiments have been presented by way of example only, and are not intended to limit the scope of the inventions. Indeed, the novel device and methods described herein may be embodied in a variety of other forms; furthermore, various omissions, substitutions and changes in the form of the device and methods described herein may be made without departing from the spirit of the inventions. The accompanying claims and their equivalents are intended to cover such forms or modifications as would fall within the scope and spirit of the inventions.

1. A method of manufacturing a semiconductor device, comprising:
forming a plurality of convex portions on a substrate;
forming a first film on upper faces and side faces of the convex portions;
forming a second film on the upper faces and the side faces of the convex portions via the first film;
removing the second film formed on upper faces of the first film to expose the upper faces of the first film;
implanting impurities into the convex portions in a state where side faces of the first film are covered with the second film and the upper faces of the first film are exposed; and
annealing the convex portions after implanting the impurities into the convex portions.

2. The method of claim 1, wherein the convex portions are annealed using a microwave.

3. The method of claim 2, wherein the convex portions are annealed using the microwave at 490° C. or more and 900° C. or less.

4. The method of claim 1, wherein the upper faces of the convex portions are crystallized by the annealing.

5. The method of claim 4, wherein the upper faces of the convex portions are changed to be single-crystalline or twin-crystaliine by the annealing.

6. The method of claim 1, wherein a width of the upper faces of the convex portions is 20 nm or less before implanting the impurities.

7. The method of claim 1, wherein a width of the upper faces of the convex portions is 20 nm or less after implanting the impurities.

8. The method of claim 1, wherein
the first film is formed such that a portion of a trench between the convex portions remains, and
the second film is formed such that the portion of the trench between the convex portions is filled up.

9. The method of claim 1, wherein
the first film is a first insulator, and
the second film is a second insulator different from the first insulator.

10. method of claim 1, wherein
the first film is a silicon oxide film, and
the second film is a silicon nitride film or a silicon carbide film.

11. The method of claim 1, wherein the removal of the second film is continued even after the upper faces of the first film are exposed.

12. The method of claim 1, wherein the removal of the second film is terminated before the upper faces of the convex portions are exposed.

13. The method of claim 1, wherein the implantation of the impurities into the convex portions causes upper portions of the convex portions to expand in an upward direction.

14. The method of claim 13, wherein the expansion of the upper portions of the convex portions changes shapes of the upper faces of the first film.

15. The method of claim 1, wherein the upper faces of the first film include a portion higher than upper faces of the second film after implanting the impurities.

16. The method of claim 1, wherein the impurities are implanted into the convex portions through the first film.

17. The method of claim 1, wherein the convex portions are formed so as to extend in a first direction and so as to be adjacent to each other in a second direction perpendicular to the first direction.

18. The method of claim 1, wherein the convex portions are device regions of the substrate and are provided between isolation regions.

19. The method of claim 1, further comprising:
forming a third film on the first and second films after annealing the convex portions;
forming an opening that penetrates the first and third films to reach a convex portion; and
forming a plug interconnect in the opening.

20. A semiconductor device comprising:
a substrate including a plurality of convex portions containing impurities;
a first film provided on upper faces and side faces of the convex portions; and
a second film provided between the side faces of the adjacent convex portions via the first film;
wherein upper faces of the first film include a portion higher than upper faces of the second film.
